(19) United States
(12) Patent Application Publication
(10) Pub. No.: US 2022/0238576 A1
(43) Pub. Date: Jul. 28, 2022

(54) IMAGING DEVICE

(71) Applicant: Panasonic Intellectual Property Management Co., Ltd., Osaka (JP)

(72) Inventor: KATSUYA NOZAWA, Osaka (JP)

(21) Appl. No.: 17/722,452

(22) Filed: Apr. 18, 2022

Related U.S. Application Data
(63) Continuation of application No. PCT/JP2020/040008, filed on Oct. 23, 2020.

(30) Foreign Application Priority Data
Nov. 15, 2019 (JP) 2019-207226
Oct. 13, 2020 (JP) 2020-172685

(51) Int. Cl. H01L 27/146

(52) U.S. Cl. CPC H01L 27/14605; H01L 27/14607; H01L 27/14643

(57) ABSTRACT

An imaging device includes pixels. Each of the pixels includes a first single-crystal semiconductor layer transmitting light, a first electrode, and a photoelectric conversion layer in contact with the first single-crystal semiconductor layer. The photoelectric conversion layer is positioned between the first single-crystal semiconductor layer and the first electrode and absorbs the light. The first single-crystal semiconductor layer, the photoelectric conversion layer, and the first electrode are arranged in order mentioned such that the light after passing through the first single-crystal semiconductor layer is incident on the photoelectric conversion layer.

### BACKGROUND

### 1. Technical Field

The present disclosure relates to an imaging device.

### 2. Description of the Related Art

An image sensor is composed of units each called a pixel and includes a plurality of the pixels arrayed two-dimensionally. Each of the pixels includes a photoelectric converter generating signal charges upon illumination with light, and a charge accumulation region accumulating the signal charges generated in the photoelectric converter. A multilayer image sensor utilizing a photoelectric conversion material, such as an organic semiconductor, a semiconductor carbon nanotube, or a semiconductor quantum dot, is known as the photoelectric converter.

### SUMMARY

In one general aspect, one non-limiting and exemplary embodiment of the techniques disclosed here features an imaging device including pixels. Each of the pixels includes a first single-crystal semiconductor layer transmitting light, a first electrode, and a photoelectric conversion layer in contact with the first single-crystal semiconductor layer. The photoelectric conversion layer is positioned between the first single-crystal semiconductor layer and the first electrode and absorbs the light. The first single-crystal semiconductor layer, the photoelectric conversion layer, and the first electrode are arranged in order mentioned such that the light after passing through the first single-crystal semiconductor layer is incident on the photoelectric conversion layer.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a graph depicting wavelength dependency of a transmittance when there is no reflection loss;

FIG. 2 is a schematic view illustrating, by way of example, a device structure of a pixel in an imaging device according to a first embodiment of the present disclosure;

FIG. 3 is a circuit diagram illustrating a configuration example of a read circuit in the first embodiment of the present disclosure;

FIG. 4A is a graph depicting a filter characteristic of a long pass filter;

FIG. 4B is a graph depicting a filter characteristic of a band pass filter;

FIG. 5 is a schematic view illustrating, by way of example, a device structure of a pixel in an imaging device according to a modification of the first embodiment of the present disclosure;

FIG. 6 is a schematic view illustrating, by way of example, a device structure of a pixel in an imaging device according to a second embodiment of the present disclosure;

FIG. 7 is a circuit diagram illustrating a configuration example of a read circuit in the second embodiment of the present disclosure;

FIG. 8 is a schematic view illustrating, by way of example, a device structure of a pixel in an imaging device according to a modification of the second embodiment of the present disclosure;

FIG. 9 is a schematic view illustrating, by way of example, a device structure of a pixel in an imaging device according to a third embodiment of the present disclosure;

FIG. 10 is a block diagram illustrating a configuration example of a distance image acquisition system according to the third embodiment of the present disclosure;

FIG. 11 is an explanatory view illustrating the principle of operation of the distance image acquisition system according to the third embodiment of the present disclosure; and

FIG. 12 is a schematic view illustrating, by way of example, a device structure of a pixel in an imaging device according to a fourth embodiment of the present disclosure.

### DETAILED DESCRIPTION

First, the underlying knowledge forming the basis of the present disclosure, found by the inventor, is explained prior to describing embodiments of the present disclosure.

A multilayer image sensor has a structure of sandwiching a photoelectric conversion layer made of a photoelectric conversion material by a pair of electrodes, and a bias voltage is applied between the pair of electrodes. The bias voltage separates a positive charge and a negative charge that are generated in the photoelectric conversion layer. As a result, either the positive charge or the negative charge can be withdrawn toward a transparent electrode side, and the other charge can be withdrawn toward a counter electrode side.

To allow light to reach the photoelectric conversion layer, the electrode material of one of the pair of electrodes has transparency for a wavelength targeted in the photoelectric conversion. The electrode made of the electrode material with the transparency is called a transparent electrode. Indium tin oxide, the so-called ITO, is widely used as the material of the transparent electrode. The transparent electrode is formed with deposition of the ITO by sputtering, and its crystallographic state is polycrystalline or amorphous. The other electrode that is not the transparent electrode is called a counter electrode. In the image sensor, signal charges are collected by the counter electrode and are transported to a charge accumulation region. In the multilayer image sensor, the charge accumulation region is typically formed in a single-crystal semiconductor layer.

Japanese Patent No. 5585232 and Japanese Unexamined Patent Application Publication No. 2015-153962 disclose a structure in which the photoelectric conversion layer is in direct contact with a single-crystal silicon substrate. Japanese Unexamined Patent Application Publication No. 2015-037121 discloses an imaging device including a first photoelectric conversion portion formed inside a single-crystal silicon substrate, and a second photoelectric conversion portion positioned above the first photoelectric conversion portion. The second photoelectric conversion portion is made of an inorganic material, and the first photoelectric conversion portion functions as an optical filter selectively absorbing light in a particular wavelength range. Japanese Unexamined Patent Application Publication No. 2018-181957 discloses an imaging device including an infrared light detector and a visible light detector, the visible light detector being positioned above the infrared light detector and formed inside a silicon substrate. The visible light detector functions as an optical filter selectively absorbing visible light.

The known transparent electrode material ITO has a problem that a high transmittance is obtained in a visible range, but a transmittance in an infrared range is low. The transmittance of a layer with a uniform film thickness is generally expressed by the following formula (1). Because a reflectance does not take a negative value, an upper limit of the transmittance is given by (100%−(absorbance))

(Transmittance)=100% −(reflectance)−(absorbance) (1)

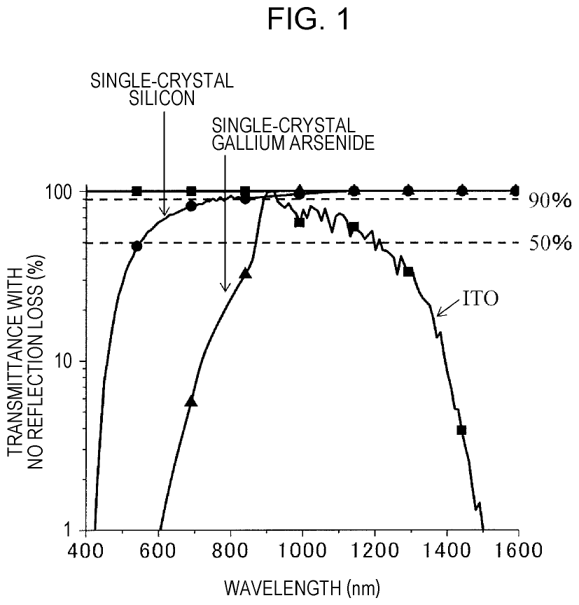

FIG. 1 depicts wavelength dependency of the transmittance when an ITO film with a thickness of 1000 nm has no reflection loss. The transmittance when there is no reflection loss is called an “ideal transmittance” hereinafter. The ideal transmittance of the ITO film for wavelengths of shorter than or equal to 1200 nm is higher than or equal to 50%. On the other hand, the ideal transmittance of the ITO film for wavelengths of longer than or equal to 1200 nm is smaller than or equal to 50%. Although the ideal transmittance of the ITO film changes somewhat depending on raw materials and formation conditions of the film, the above-described tendency does not change. The longer the wavelength, the lower the ideal transmittance. The ideal transmittance for a wavelength of 1400 nm, for example, is about 10%.

The related-art multilayer image sensor utilizing the ITO film as the transparent electrode can photoelectrically convert only light having passed through the ITO film. It is, therefore, impossible to realize quantum efficiency of higher than or equal to 50% for light with a wavelength of longer than or equal to 1200 nm. Here, the quantum efficiency is expressed by a ratio of the number of captured signal charges to the number of photons of incident light. Because sensitivity of the image sensor basically depends on the quantum efficiency, the related-art multilayer image sensor is difficult to realize high sensitivity for the light with the wavelength of longer than or equal to 1200 nm.

On the basis of the above-described knowledge, the inventor has succeeded in finding a novel structure capable of suppressing a reduction in sensitivity of imaging in a wavelength range on a longer wavelength side than the visible range, particularly in a near-infrared range. For example, the visible range is a wavelength range from about 400 nm to 700 nm, and the near-infrared range is a wavelength range from about 700 nm to 2500 nm.

According to one aspect, the present disclosure is summarized as follow.

### [Item 1]

An imaging device according to Item 1 of the present disclosure includes pixels. Each of the pixels includes:
a first single-crystal semiconductor layer transmitting light;
a first electrode; and
a photoelectric conversion layer in contact with the first single-crystal semiconductor layer, the photoelectric conversion layer being positioned between the first single-crystal semiconductor layer and the first electrode and absorbing the light.

The first single-crystal semiconductor layer, the photoelectric conversion layer, and the first electrode are arranged in order mentioned such that the light after passing through the first single-crystal semiconductor layer is incident on the photoelectric conversion layer.

With the imaging device according to Item 1, a reduction in sensitivity of imaging in a wavelength range on a longer wavelength side than a visible range, particularly in a near-infrared range, can be suppressed.

### [Item 2]

The imaging device according to Item 1 may further include a bias voltage control circuit electrically connected to at least one selected from the group consisting of the first single-crystal semiconductor layer and the first electrode, the bias voltage control circuit applying a bias voltage to the photoelectric conversion layer.

With the imaging device according to Item 2, the application of the bias voltage makes it easier to collect, for example, positive charges by a counter electrode and negative charges by the first single-crystal semiconductor layer.

### [Item 3]

In the imaging device according to Item 1 or 2, each of the pixels may further include a charge accumulation region positioned in the first single-crystal semiconductor layer and accumulating charges generated in the photoelectric conversion layer.

With the imaging device according to Item 3, since a portion collecting the charges and the charge accumulation region are both formed inside the first single-crystal semiconductor layer, the so-called kTC noise can be reduced.

### [Item 4]

In the imaging device according to Item 3, each of the pixels may further include a read circuit positioned in the first single-crystal semiconductor layer and reading out the charges accumulated in the charge accumulation region.

With the imaging device according to Item 4, the read circuit can be integrated in the first single-crystal semiconductor layer.

### [Item 5]

In the imaging device according to Item 1 or 2, each of the pixels may further include:
a second single-crystal semiconductor layer; and
a charge accumulation region positioned in the second single-crystal semiconductor layer and accumulating charges generated in the photoelectric conversion layer.

The first electrode may be positioned between the first single-crystal semiconductor layer and the second single-crystal semiconductor layer.

With the imaging device according to Item 5, another variation of the imaging device is provided.

### [Item 6]

In the imaging device according to Item 5, each of the pixels may further include a read circuit positioned in the second single-crystal semiconductor layer and reading out the charges accumulated in the charge accumulation region.

With the imaging device according to Item 6, the read circuit can be integrated in the second single-crystal semiconductor layer.

### [Item 7]

In the imaging device according to any one of Items 1 to 6, each of the pixels may further include:
an on-chip lens; and
a filter layer positioned between the on-chip lens and the first single-crystal semiconductor layer, the filter layer selectively transmitting light in a first wavelength range.

With the imaging device according to Item 7, when the imaging device is illuminated with the light, absorption of the light in the single-crystal semiconductor layer can be suppressed, and a larger amount of the light can be introduced to reach the photoelectric conversion layer.

### [Item 8]

In the imaging device according to Item 7, the filter layer may have a filter characteristic having a transmission region in the first wavelength range and a cutoff region in a second wavelength range shorter than the first wavelength range.

With the imaging device according to Item 8, a long pass filter can be applied to the filter layer.

### [Item 9]

In the imaging device according to Item 7, the filter layer may have a filter characteristic having a transmission region in the first wavelength range, a first cutoff region in a second wavelength range shorter than the first wavelength range, and a second cutoff region in a third wavelength range longer than the first wavelength range.

With the imaging device according to Item 9, a band pass filter can be applied to the filter layer.

### [Item 10]

In the imaging device according to Item 7, the filter layer may have a filter characteristic having a cutoff region in a wavelength range in which the first single-crystal semiconductor layer absorbs light.

With the imaging device according to Item 10, noise and a malfunction can be suppressed which may be caused by the first single-crystal semiconductor layer absorbing the light.

### [Item 11]

In the imaging device according to any one of Items 1 to 10, the first single-crystal semiconductor layer may be made of silicon, and
the photoelectric conversion layer may absorb light having a wavelength of 1100 nm or longer.

With the imaging device according to Item 11, an absorbance can be made substantially 0 in the wavelength range of 1100 nm or longer, and hence a larger amount of the light can be introduced to reach the photoelectric conversion layer when near-infrared light is detected.

### [Item 12]

In the imaging device according to any one of Items 1 to 11, the photoelectric conversion layer may be made of a material selected from the group consisting of an organic semiconductor, a semiconductor carbon nanotube, and a semiconductor quantum dot.

With the imaging device according to Item 12, variations of the material of the photoelectric conversion layer are provided.

### [Item 13]

In the imaging device according to Item 1 or 2, each of the pixels may further include:
a charge collection region positioned in the first single-crystal semiconductor layer and collecting charges generated in the photoelectric conversion layer;
a first charge accumulation region positioned in the first single-crystal semiconductor layer, the first charge accumulation region being different from the charge collection region and accumulating the charges;
a second charge accumulation region positioned in the first single-crystal semiconductor layer, the second charge accumulation region being different from the charge collection region and accumulating the charges;
a second electrode electrically insulated from the first charge accumulation region;
a third electrode electrically insulated from the second charge accumulation region;
a first channel region positioned between the charge collection region and the first charge accumulation region; and
a second channel region positioned between the charge collection region and the second charge accumulation region.

In the imaging device according to Item 13, the second electrode may be positioned near the first charge accumulation region, and the third electrode may be positioned near the second charge accumulation region.

### [Item 14]

In the imaging device according to Item 13, movement of the charges in the first channel region from the charge collection region to the first charge accumulation region may be controlled by controlling a voltage applied to the second electrode, and
movement of the charges in the second channel region from the charge collection region to the second charge accumulation region may be controlled by controlling a voltage applied to the third electrode.

### [Item 15]

The imaging device according to Item 1 or 2 may further include an avalanche amplification mechanism capable of generating avalanche amplification.

### [Item 16]

In the imaging device according to Item 15, the avalanche amplification mechanism may include;
a first region positioned in the first single-crystal semiconductor layer and collecting charges generated in the photoelectric conversion layer; and
a second region positioned in the first single-crystal semiconductor layer and being in contact with the first region.

A polarity of the first region may be different from a polarity of the second region.

### [Item 17]

In the imaging device according to Item 16, the avalanche amplification mechanism may further include a third region positioned in the first single-crystal semiconductor layer and being in contact with the second region,
the third region may have the same polarity as the second region, and
a dopant concentration of the third region may be higher than a dopant concentration of the second region.

The embodiments of the present disclosure will be described in detail below with reference to the drawings. It is to be noted that any of the following embodiments represents a general or specific example. Numerical values, shapes, materials, constituent elements, arrangements and connection forms of the constituent elements, steps, order of the steps, etc., which are described in the following embodiments, are merely illustrative and are not purported to limit the scope of the present disclosure. The embodiments described in this Specification can be combined with each other insofar as there are no contradictions. Among the constituent elements in the following embodiments, those ones not stated in independent Claims representing the most-significant concept are explained as optional constituent elements. In the following, the constituent elements with substantially the same functions are denoted by common reference sings, and duplicate description of those constituent elements is omitted in some cases. Moreover, to avoid the drawings from becoming excessively complicated, some of the constituent elements are omitted from the drawings depending on the cases.

Terms indicating specific directions or positions (such as “upper”, “lower”, “right”, “left”, and other expressions including those words) are often used. However, those terms are merely used for easier understanding of relative directions or positions in the referred drawings. Insofar as relations between the relative directions or positions represented by the terms, such as “upper” and “lower”, in the referred drawings are the same, the constituent elements are not always requited in actual products and so on to have the same arrangements as those in the referred drawings.

### First Embodiment

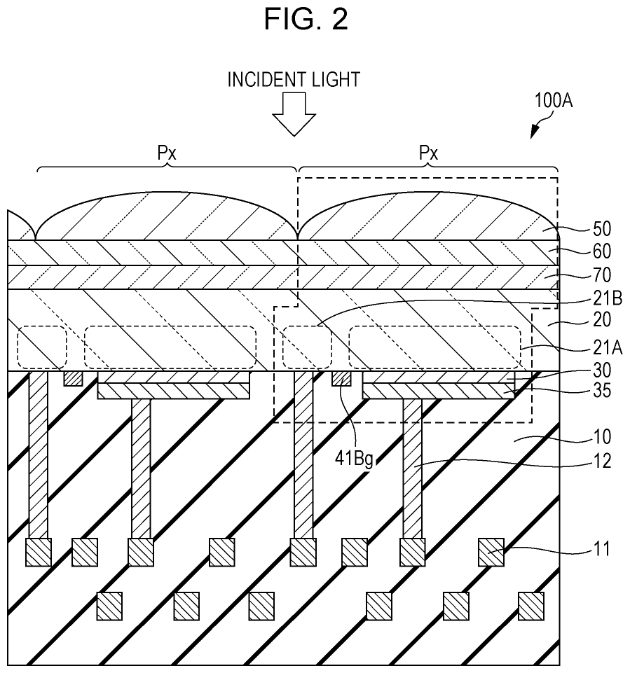

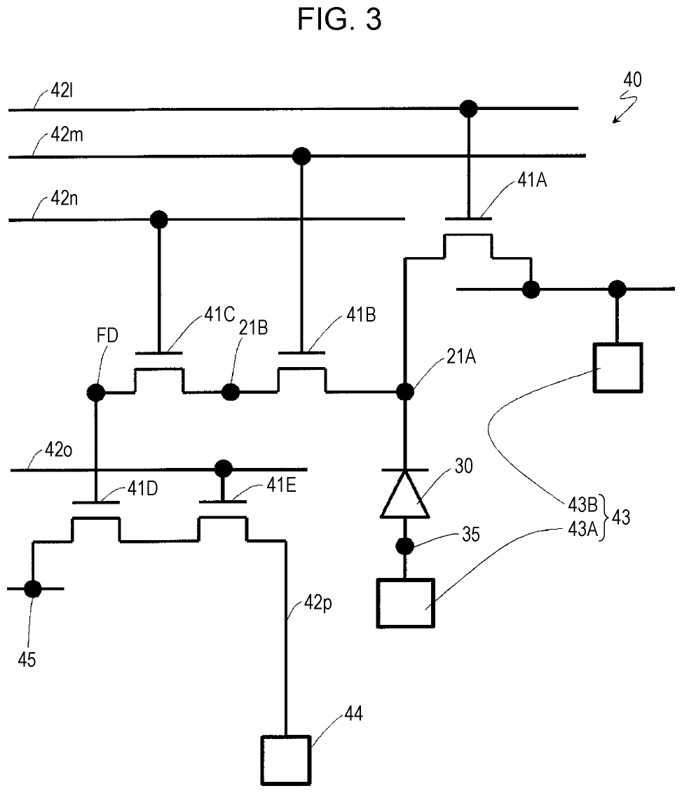

FIG. 2 is a schematic view illustrating, by way of example, a device structure of a pixel Px in an imaging device 100A according to a first embodiment. In FIG. 2, a cross-section of part of the imaging device 100A is schematically illustrated, and an area constituting the pixel Px is denoted by a dashed line. FIG. 3 is a circuit diagram illustrating a configuration example of a read circuit 40. The imaging device 100A includes two-dimensionally arranged pixels Px. The number of the pixels Px may be several millions or several tens of millions. However, the number and layout of the pixels Px can be optionally selected. When an imaging device includes at least one pixel Px, the imaging device can be utilized as a photodetector. When the pixels Px are arrayed one-dimensionally, the imaging device 100A can be utilized as, for example, a line sensor.

A structure and operation of the imaging device 100A are summarized as follows.

The imaging device 100A has the structure in which signal charges collected into a single-crystal semiconductor layer 20, namely a first single-crystal semiconductor layer, are accumulated in a charge accumulation region 21A formed inside the same single-crystal semiconductor layer 20. Thus, the signal charges generated in a photoelectric conversion layer 30 are collected into the single-crystal semiconductor layer 20 and are accumulated in the charge accumulation region 21A formed inside the same single-crystal semiconductor layer 20. The signal charges accumulated in the charge accumulation region 21A are read out by the read circuit 40 and are sent to a column signal processing circuit 44.

The imaging device 100A includes the two-dimensionally arrayed pixels Px and an insulating layer 10. The imaging device 100A may further include the column signal processing circuit 44 described later, and so on. Each of the pixels Px includes the single-crystal semiconductor layer 20, the photoelectric conversion layer 30, a counter electrode 35, and an on-chip lens 50. The on-chip lens 50 has a function of improving imaging characteristics depending on the situations. However, the on-chip lens 50 is not an essential component to be arranged. Although not illustrated, the imaging device 100A may include a support substrate for supporting a multilayer structure of the pixels Px and the insulating layer 10.

The single-crystal semiconductor layer 20 is arranged on the insulating layer 10 and is positioned between the on-chip lens 50 and the insulating layer 10. One example of a material of the single-crystal semiconductor layer 20 is single-crystal silicon. Other examples of the material of the single-crystal semiconductor layer 20 may be single-crystal gallium arsenide, single-crystal germanium, single-crystal gallium nitride, and single-crystal silicon germanium.

The single-crystal semiconductor layer 20 transmits light therethrough and has a significant transmittance for a wavelength targeted in the photoelectric conversion that is performed by the photoelectric conversion layer 30 described later, namely for a target wavelength. The term “significant transmittance” implies the ideal transmittance at which imaging can be performed with the photoelectric conversion by the photoelectric conversion layer 30. A criterion for the significant transmittance is the ideal transmittance of higher than or equal to 50%, for example. With the photoelectric conversion layer 30 having a higher ideal significant transmittance, the imaging can be performed at a lower illuminance. The target wavelength in the photoelectric conversion corresponds to a wavelength of light absorbed by the photoelectric conversion layer 30. When it is said that the photoelectric conversion layer absorbs light at a certain wavelength, the photoelectric conversion layer is not always required to exhibit an absorbance of 100% for the light at that wavelength.

In a single-crystal semiconductor, there is a wavelength called an absorption edge wavelength λg. The absorption edge wavelength λg is a wavelength corresponding to energy of a band gap. An absorption coefficient is substantially 0 for light with a wavelength of longer than or equal to λg, and the light with the wavelength of longer than or equal to λg passes through the single-crystal semiconductor layer. For example, the absorption edge wavelength of the single-crystal silicon is about 1100 nm. The absorption edge wavelength of the single-crystal gallium arsenide is about 1000 nm. The absorption edge wavelength of the single-crystal gallium nitride is about 376 nm.

In this embodiment, a material with the absorption edge wavelength λg shorter than the target wavelength in the photoelectric conversion is selected as the material of the single-crystal semiconductor layer 20. Selection of such a material is effective in suppressing generation of charges that are unintentionally generated due to absorption of light by the single-crystal semiconductor layer 20. For example, when the single-crystal semiconductor layer 20 is made of the single-crystal gallium nitride, the absorption coefficient of the single-crystal semiconductor layer 20 can be made substantially 0 over the entirety of the visible range. When the single-crystal semiconductor layer 20 is made of the single-crystal silicon, the absorption coefficient of the single-crystal semiconductor layer 20 can be made substantially 0 in a wavelength range of longer than or equal to 1100 nm. The wavelength range of longer than or equal to 1100 nm includes wavelengths in a range from 1350 nm to 1450 nm where sunlight is strongly attenuated, or wavelengths of around 1500 nm which are widely utilized in optical fiber communication.

The material of the single-crystal semiconductor layer 20 may be a material with the absorption edge wavelength λg longer than the target wavelength in the photoelectric conversion. For example, in the case of an indirect gap semiconductor such as the single-crystal silicon, when a thickness of the single-crystal semiconductor layer 20 is thin, absorption of light with a shorter wavelength than the absorption edge can also be suppressed.

Refer to FIG. 1 again. FIG. 1 depicts the ideal transmittance of a single-crystal silicon film with a thickness of 1000 nm as well. For reference, FIG. 1 further depicts the ideal transmittance of the single-crystal gallium arsenide. The single-crystal silicon film with the thickness of 1000 nm exhibits the ideal transmittance of higher than or equal to 50% for wavelengths of longer than or equal to about 550 nm and exhibits the ideal transmittance of higher than or equal to 90% for wavelengths of longer than or equal to about 800 nm. Accordingly, when the single-crystal silicon film with the thickness of 1000 nm is formed as the single-crystal semiconductor layer 20, higher than or equal to 90% of the light with the wavelength of longer than or equal to 800 nm can ideally pass through the single-crystal semiconductor layer 20 and can reach the photoelectric conversion layer 30.

The photoelectric conversion layer 30 is positioned between the single-crystal semiconductor layer 20 and the counter electrode 35. More specifically, the photoelectric conversion layer 30 is in contact with the single-crystal semiconductor layer 20 and is sandwiched between the charge accumulation region 21A formed in the single-crystal semiconductor layer 20 and the counter electrode 35. The photoelectric conversion layer 30 absorbs the light having passed through the single-crystal semiconductor layer 20. When the single-crystal semiconductor layer 20 is made of silicon, the photoelectric conversion layer 30 absorbs the light with the wavelength of longer than or equal to 1100 nm. Even for light with wavelength shorter than the absorption edge wavelength λg of the single-crystal semiconductor layer 20, the photoelectric conversion layer 30 can absorb the light at a wavelength at which the single-crystal semiconductor layer 20 exhibits a sufficient ideal transmittance.

In this Specification, a section constituted by the single-crystal semiconductor layer 20, the photoelectric conversion layer 30, and the counter electrode 35 is called a “photoelectric conversion section”. Part of the single-crystal semiconductor layer 20 functions as a pixel electrode in the related art. The photoelectric conversion layer 30 and the counter electrode 35 are positioned inside the insulating layer 10. The single-crystal semiconductor layer 20 is positioned on a side where light is incident on the photoelectric conversion section with respect to the photoelectric conversion layer 30, and the counter electrode 35 is positioned on an opposite side to the single-crystal semiconductor layer 20 with respect to the photoelectric conversion layer 30.

The counter electrode 35 does not need to be transparent to the light incident on the photoelectric conversion section. The counter electrode 35 may be made of, for example, a metal such as Al or Ag, or metal nitride such as TiN. The counter electrode 35 may be made of a material reflecting the light incident on the photoelectric conversion layer 30. The counter electrode 35 may have a reflectance of higher than or equal to 80%, for example, for the light with the wavelength of longer than or equal to 1100 nm. An example of such a material is Al or Au. With the counter electrode 35 exhibiting a high reflectance of higher than or equal to 80%, for example, for the light with the wavelength of longer than or equal to 1100 nm, the counter electrode 35 can reflect the light having passed through the photoelectric conversion layer 30 toward the single-crystal semiconductor layer 20 such that a larger amount of the light contributes to the photoelectric conversion. In other words, imaging with higher sensitivity is expected to be realized in the near-infrared range.

Hole-electron pairs including positive charges and negative charges are generated upon the photoelectric conversion layer 30 absorbing light. The single-crystal semiconductor layer 20 collects either holes or electrons of the hole-electron pairs, and the counter electrode 35 collects the other charges of the hole-electron pairs. The charges collected into the single-crystal semiconductor layer 20 are accumulated in the charge accumulation region 21A. In this embodiment, the charge accumulation region 21A is present inside the single-crystal semiconductor layer 20 independently for each pixel Px. The charge accumulation region 21A may be in direct contact with the photoelectric conversion layer 30. Alternatively, a charge collection region formed by a portion of the single-crystal semiconductor layer 20, the portion being in contact with the photoelectric conversion layer 30, may perform only collection of the charges, and the charge accumulation region 21A may be arranged at a place away from the photoelectric conversion layer 30 by a distance through which the charges are movable. For example, the charge collection region and the charge accumulation region 21A may be connected via a partial region of the single-crystal semiconductor layer 20 or may be electrically connected by a conductive plug.

When the charge collection region and the charge accumulation region 21A are both formed in the same single-crystal semiconductor layer 20 and are electrically connected to each other through the single-crystal semiconductor with no metal interposed therebetween, the charges collected into the charge collection region can be completely transferred to the charge accumulation region 21A. Furthermore, when the charge accumulation region 21A is made of the single-crystal semiconductor, the charges accumulated in the charge accumulation region 21A can be completely purged out. Those characteristics are effective in reducing noise caused by part of the collected or accumulated charges remaining unintentionally, namely the so-called kTC noise.

The charge accumulation region 21A formed inside the single-crystal semiconductor layer 20 is formed by changing the polarity of an impurity doped into the relevant region to be different from that of an impurity doped into a surrounding region. For example, in the case of causing the single-crystal semiconductor layer 20 to collect the positive charges, the doping just needs to be performed such that the charge accumulation region 21A becomes the p-type and the surrounding region becomes the n-type. In the case of causing the single-crystal semiconductor layer 20 to collect the negative charges, the doping just needs to be performed such that the charge accumulation region 21A becomes the n-type and the surrounding region becomes the p-type. The charges accumulated in the charge accumulation region 21A are finally transferred to the column signal processing circuit 44 illustrated in FIG. 3. Details of the column signal processing circuit 44 will be described later.

Another charge accumulation region 21B different from the charge accumulation region 21A may be further formed inside the single-crystal semiconductor layer 20. Although described in detail later, electrical conductivity of a channel region of a transfer transistor formed between the charge accumulation region 21A and the charge accumulation region 21B can be controlled with a potential applied to a gate electrode of the transfer transistor. Accordingly, the charges accumulated in the charge accumulation region 21A are movable to the charge accumulation region 21B through a channel of the transfer transistor. However, the charge accumulation region 21B is not essential.

The photoelectric conversion layer 30 contains a photoelectric conversion material with a significant absorption coefficient for the target wavelength in the photoelectric conversion. The significant absorption coefficient implies an absorption coefficient necessary for realizing sensitivity enough to enable imaging to be performed at the target wavelength. Examples of the photoelectric conversion material are an organic semiconductor, a semiconductor carbon nanotube, and a semiconductor quantum dot.

The photoelectric conversion layer 30 may include an electron blocking layer or a hole blocking layer (not illustrated). Such a blocking layer can prevent unintended charges from being injected to the photoelectric conversion layer 30 from the electrode and so on. A material of the electron blocking layer is, for example, PEDOT:PSS, and a material of the hole blocking layer is, for example, C60.

The photoelectric conversion layer 30 may contain a material with a quantum nanostructure having a quantum confinement effect. The quantum nanostructure implies a structure of developing a quantum size effect one-dimensionally, two-dimensionally, or three-dimensionally. An example of the material with the quantum nanostructure is a carbon nanotube. The carbon nanotube has a structure such as obtained by rounding a graphene and has a substantially cylindrical seamless shape with a diameter in a nanometer range. A carbon nanotube with a structure including one cylinder is especially called a single-layer carbon nanotube, and a carbon nanotube with a nested structure of cylinders is called a multilayer carbon nanotube. Many of electronic characteristics and optical characteristics of the single-layer carbon nanotube are determined depending on chirality that is designated by a chiral index. The single-layer carbon nanotube exhibits metallic properties or semiconductor properties depending on the chirality.

Energy of an electron in the single-layer carbon nanotube is specified only by a wave number in a tube axial direction due to periodicity resulting from that the nanotube has the cylindrical shape. In other words, an electron state in the single-layer carbon nanotube is one-dimensional. A band structure of the single-layer carbon nanotube is featured in that sub-bands specified by energy levels according to divergence of state density appear discretely. Such a singular point in the state density is called the Van Hove singular point.

An absorption spectrum of the single-layer carbon nanotube exhibits a sharp peak at a wavelength corresponding to energy between the sub-bands. In the carbon nanotube, an optical transition between a first pair of sub-bands counting from the Fermi level is a first optical transition, and an optical transition between a second pair of sub-bands is a second optical transition.

Examples of the organic semiconductor are low-molecular semiconductors represented by, for example, phthalocyanines such as lead phthalocyanine and copper phthalocyanine, and by naphthalocyanines, and semiconductor polymers such as P3HT, PDDTT, and PDTTP. Photoelectric conversion materials using organic semiconductors are described in detail in, for example, Journal of Materials Chemistry C, 2018, 6, 3499. For reference, the contents disclosed in the above-mentioned document is to be all incorporated in this Specification.

The semiconductor carbon nanotube implies the single-layer carbon nanotube of the type exhibiting semiconductor properties. The single-layer carbon nanotube is featured by the chirality and has a specific resonance absorption wavelength that is different depending on the chirality. The semiconductor carbon nanotube specifically exhibits a high absorption coefficient at the resonance absorption wavelength. For example, the semiconductor carbon nanotube with the chiral index (9, 8) exhibits resonance absorption at each of a wavelength around 800 nm and a wavelength around 1410 nm. The semiconductor carbon nanotube with the chiral index (7, 6) exhibits resonance absorption at each of a wavelength around 650 nm and a wavelength around 1130 nm. Wavelength values indicated in Table 1, given below, are merely exemplary values, and there may be an error of about 50 nm relative to an actually measured value.

TABLE 1

| Chirality | (7, 6) | (8, 7) | (9, 8) |
|---|---|---|---|
| Wavelength according to first | 1130 nm | 1280 nm | 1410 nm |
| optical transition (corresponding | | | |
| to E11 transition) | | | |
| Wavelength according to second | 650 nm | 730 nm | 800 nm |
| optical transition (corresponding | | | |
| to E22 transition) | | | |

The semiconductor quantum dot is a structured body including a semiconductor core with a diameter in a range from about several nanometers to several ten nanometers and is composed of about several tens of atoms. A material of the semiconductor core forming the quantum dot is, for example, cadmium sulfide, lead sulfide, cadmium selenide, or lead selenide. A quantum mechanical effect is produced by restricting a semiconductor size to the range from about several nanometers to several ten nanometers. The semiconductor quantum dot exhibits resonance absorption at a shorter wavelength than a bulk semiconductor. The semiconductor quantum dot exhibits a three-dimensional quantum confinement effect. A resonance absorption wavelength of the semiconductor quantum dot is determined mainly depending on the material and the size of the core.

A surface of the semiconductor quantum dot may be modified with, for example, a dispersant or a ligand. The semiconductor quantum dot may be a quantum dot of a perovskite structure expressed by a chemical formula APbX₃. In the chemical formula APbX₃, A denotes one selected from the group consisting of cesium, methylammonium, and formamidinium, and X denotes chlorine, bromine, or iodine.

When a particle size is smaller than or equal to about the Bohr radius of an exciton, the exciton and an electron are confined three-dimensionally in a space, and the state density of those particles becomes discrete unlike the case in a bulk state. Furthermore, as the particle size reduces, the quantum confinement effect increases, and an energy gap is widened. Even for the same raw material, therefore, a greater energy gap than that in the bulk state can be realized by bringing the material into a quantum dot state, and the energy gap can be adjusted depending on the particle size.

In the semiconductor quantum dot, a width of an absorption peak according to the first optical transition may greatly change depending on the raw material and the particle size of the quantum dot. Accordingly, when the semiconductor quantum dot is selected, by way of example, as the photoelectric conversion material of the photoelectric conversion layer, the resonance absorption wavelength at which the photoelectric conversion layer 30 specifically exhibits the absorption coefficient can be adjusted by adjusting the raw material and the particle size of the quantum dot.

The photoelectric conversion layer 30 may contain other molecules than the organic semiconductor, the semiconductor carbon nanotube, and the semiconductor quantum dot. For example, the photoelectric conversion layer 30 may contain fullerenes, such as C60 and PCBM, together with the organic semiconductor and the semiconductor carbon nanotube. Because C60 and PCBM do not absorb infrared light, they do not contribute to the photoelectric conversion in the infrared range.

As described above, hole-electron pairs are generated upon the photoelectric conversion layer 30 absorbing light. The single-crystal semiconductor layer 20 collects either holes or electrons of the hole-electron pairs, and the counter electrode 35 collects the other charges of the hole-electron pairs. In this embodiment, the single-crystal semiconductor layer 20 collects positive charges, and the counter electrode 35 collects negative charges. Efficiency of collecting those charges is increased in some cases by applying a bias voltage between the single-crystal semiconductor layer 20 and the counter electrode 35.

The positive charges have properties of moving toward a lower potential side, and the negative charges have properties of moving toward a higher potential side. Therefore, the counter electrode 35 is easier to collect the positive charges and the single-crystal semiconductor layer 20 is easier to collect the negative charges by applying the bias voltage in a manner of relatively reducing a potential of the counter electrode 35 and relatively increasing a potential of the single-crystal semiconductor layer 20. To the contrary, the counter electrode 35 is easier to collect the negative charges and the single-crystal semiconductor layer 20 is easier to collect the positive charges by applying the bias voltage in a manner of relatively increasing the potential of the counter electrode 35 and relatively reducing the potential of the single-crystal semiconductor layer 20. Here, the word “relatively” implies the case of comparing the bias voltage with that when the bias voltage is not applied. The bias voltage can be applied by using, for example, a bias voltage control mechanism 43, illustrated in FIG. 3, which is connected to the single-crystal semiconductor layer 20 and/or the counter electrode 35. Details of the bias voltage control mechanism 43 will be described later.

The insulating layer 10 typically has a multilayer structure including interlayer insulating layers laminated one above the other. The layers constituting the insulating layer 10 are made of, for example, silicon dioxide. In the insulating layer 10, there may be multilayer wirings including wirings 11 extending in a direction perpendicular to the drawing sheet and wirings 12 extending in a direction along the drawing sheet. The multilayer wirings are positioned under the single-crystal semiconductor layer 20. The multilayer wirings are made of, for example, Cu and include vias (not illustrated) connecting the wirings in different layers to each other. The charge accumulation region in the single-crystal semiconductor layer 20 is electrically connected to the read circuit 40 via the wirings 11 and 12. The counter electrode 35 is electrically connected to the bias voltage control mechanism 43 via the wirings 11 and 12.

A configuration example of the read circuit 40 is described with reference to FIG. 3. The read circuit 40 reads out the charges accumulated in the charge accumulation region. The read circuit 40 includes a reset transistor 41A, a transfer transistor 41B, a read transistor 41C, an amplifier transistor 41D, and a selection transistor 41E. However, the transfer transistor 41B and the read transistor 41C are not essential.

In this embodiment, the read circuit 40 is formed inside the single-crystal semiconductor layer 20 in which the charge accumulation region 21A is present. A channel region, a source region, and a drain region of each of the above-mentioned transistors can be integrated in the single-crystal semiconductor layer 20. Each transistor is, for example, an n-channel MOSFET or a p-channel MOSFET. The read circuit 40 is connected to the bias voltage control mechanism 43 including bias voltage control circuits 43A and 43B and to the column signal processing circuit 44. Only a gate 41Bg of the transfer transistor 41B in the read circuit 40 is illustrated in FIG. 2.

The bias voltage control circuit 43A is connected to the counter electrode 35 of the photoelectric conversion section, and the bias voltage control circuit 43B is connected to the single-crystal semiconductor layer 20 via the reset transistor 41A. The bias voltage control circuit 43A supplies a constant voltage to the counter electrode 35. The potential of the counter electrode 35 is thereby kept constant. On the other hand, the bias voltage control circuit 43B applies a predetermined reset voltage to the charge accumulation region 21A. The potential of the charge accumulation region 21A can be set to a reference value by holding the reset transistor 41A in an on-state until a time immediately before exposure. Because the two bias voltage control circuits 43A and 43B apply different voltages to the counter electrode 35 and the charge accumulation region 21A, respectively, a desired bias voltage can be applied to the photoelectric conversion layer 30 sandwiched between the counter electrode 35 and the charge accumulation region 21A. The bias voltage control circuits 43A and 43B are each, for example, a constant voltage source, a variable voltage source, or a ground line. The bias voltage control circuits 43A and 43B may be circuits formed inside the imaging device 100A or circuits externally connected to the imaging device 100A. It is to be noted that the bias voltage control mechanism 43 is not essential and the application of the bias voltage is also not essential.

Depending on the type of the material of the photoelectric conversion layer 30, significant sensitivity is obtained only when the bias voltage is applied to the photoelectric conversion layer. In such a case, the bias voltage control mechanism 43 may have the function of an electronic shutter.

The reset transistor 41A initializes the potential of the charge accumulation region 21A to the reference value. A gate of the reset transistor 41A is electrically connected to a reset signal line 421. A vertical scanning circuit (not illustrated) controls turning-on and—off of the reset transistor 41A via the reset signal line 421. Either a source or a drain of the reset transistor 41A is connected to the bias voltage control circuit 43B, and the other is connected to the charge accumulation region 21A.

The transfer transistor 41B transfers the charges accumulated in the charge accumulation region 21A to the charge accumulation region 21B. A gate of the transfer transistor 41B is electrically connected to a transfer control line 42m. The vertical scanning circuit controls turning-on and -off of the transfer transistor 41B via the transfer control line 42m. Either a source or a drain of the transfer transistor 41B is connected to the charge accumulation region 21A, and the other is connected to the charge accumulation region 21B.

The read transistor 41C transfers the charges accumulated in the charge accumulation region 21B to a floating diffusion node FD. A gate of the read transistor 41C is electrically connected to a read control line 42n. The vertical scanning circuit controls turning-on and -off of the read transistor 41C via the read control line 42n. Either a source or a drain of the read transistor 41C is connected to the floating diffusion node FD, and the other is connected to the charge accumulation region 21B.

The amplifier transistor 41D functions as a source follower that outputs a signal corresponding to a potential at the floating diffusion node FD. A gate of the amplifier transistor 41D is connected to the floating diffusion node FD. Either a source or a drain of the amplifier transistor 41D is connected to a power supply line 45, and the other is connected to either a source or a drain of the selection transistor 41E.

The selection transistor 41E selects a target one of the amplifier transistors 41D each disposed per pixel, the one being to be connected to the column signal processing circuit 44. A gate of the selection transistor 41E is electrically connected to an address control line 42o. The vertical scanning circuit controls turning-on and -off of the selection transistor 41E via the address control line 42o. Either a source or a drain of the selection transistor 41E is connected to the other of the source and the drain of the amplifier transistor 41D, and the other of the source and drain of the selection transistor 41E is connected to the column signal processing circuit 44 via an output signal line 42p.

The column signal processing circuit 44 functions as a charge counter. The column signal processing circuit 44 includes an analog-digital conversion circuit and is connected to the output signal line 42p. The column signal processing circuit 44 may further include a circuit for performing noise-suppression signal processing that is represented by correlated double sampling. The column signal processing circuit 44 may be a circuit formed inside the single-crystal semiconductor layer 20. Alternatively, the column signal processing circuit 44 may be a circuit formed in another single-crystal semiconductor layer different from the single-crystal semiconductor layer 20 or may be a circuit externally connected to the imaging device 100A.

The operation of the imaging device 100A will be described below. The following description is made in connection with an example in which the single-crystal semiconductor layer 20 collects the positive charges of the charge pairs. In the case of causing the single-crystal semiconductor layer 20 to collect the negative charges, it is just required to change the polarities of the related materials and so on. Because a technique for realizing such a change is obvious to those skilled in the art, detailed description of the technique is omitted.

The incident light is condensed by the on-chip lens 50 and, after passing through the single-crystal semiconductor layer 20, reaches the photoelectric conversion layer 30. The light incident on the photoelectric conversion layer 30 is absorbed, whereby the charge pairs of the positive charges and the negative charges are generated in the photoelectric conversion layer 30. The positive charges are collected into the single-crystal semiconductor layer 20, and the negative charges are collected into the counter electrode 35. The positive charges collected into the single-crystal semiconductor layer 20 are accumulated in the charge accumulation region 21A.

The charge accumulation region 21A is brought into a floating state by turning off the reset transistor 41A at the time of starting exposure. The positive charges generated in the photoelectric conversion layer 30 are accumulated in the charge accumulation region 21A, and the potential of the charge accumulation region 21A is changed depending on an amount of the accumulated charges. After the end of the exposure, the transfer transistor 41B is turned on to transfer the charges accumulated in the charge accumulation region 21A to the charge accumulation region 21B.

The charges accumulated in the charge accumulation region 21B are transferred to the floating diffusion node FD by turning on the read transistor 41C. An output of the amplifier transistor 41D is changed depending on the amount of the charges transferred to the floating diffusion node FD. The column signal processing circuit 44 processes an output signal output from the amplifier transistor 41D selected by the selection transistor 41E and finally measures the charge amount.

According to this embodiment, the charge accumulation regions 21A and 21B are formed inside the same single-crystal semiconductor layer 20. While the amount of the charges accumulated in the charge accumulation region 21B is being measured, new charges can be accumulated in the charge accumulation region 21A. Thus, the exposure can be performed at the same time as measuring the charge amount, and the so-called global shutter function is realized.

The pixel Px may further include a filter layer 60 and a protective layer 70. In the example illustrated in FIG. 2, the protective layer 70, the filter layer 60, and the on-chip lens 50 are laminated on the single-crystal semiconductor layer 20 in order mentioned.

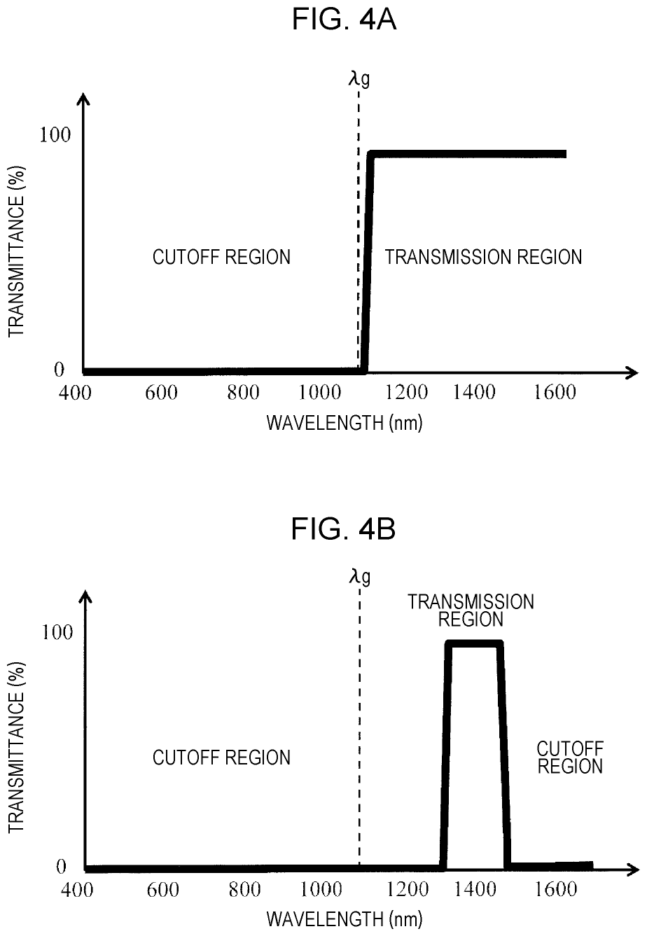

A transmittance characteristic of the filter layer 60 will be described in detail below with reference to FIGS. 4A and 4B.

FIG. 4A is a graph depicting a filter characteristic of a long pass filter. FIG. 4B is a graph depicting a filter characteristic of a band pass filter.

The filter layer 60 is positioned between the on-chip lens 50 and the single-crystal semiconductor layer 20 and selectively transmits light in a particular wavelength range therethrough. A transmittance of the filter layer 60 depends on wavelength. A long pass filter or a band pass filter can be applied to the filter layer 60. A wavelength range where the filter exhibits significantly high transparency is indicated as a “transmission range”, and a wavelength range where the filter exhibits significantly low transparency is indicated as a “cutoff range”. The significantly high transparency implies a transmittance of higher than or equal to 90%, for example, and the significantly low transparency implies a transmittance of lower than or equal to 10%, for example.

A filter having the transmission region in a wavelength range with a lower limit wavelength longer than a particular wavelength and having the cutoff region in a wavelength range with an upper limit wavelength shorter than the particular wavelength is defined as the long pass filter. On the other hand, a filter having the transmission region in a particular wavelength range and having the cutoff regions in a shorter wavelength range and a longer wavelength range positioned on both sides of the particular wavelength range in a sandwiching relation is defined as the band pass filter. The filter layer 60 may be any of the band pass filter and the long pass filter insofar as the wavelength intended to be used in the imaging falls within the transmission range. An example of the particular wavelength is the absorption edge wavelength λg.

A filter having the cutoff region in a wavelength range where the single-crystal semiconductor layer 20 has a high absorption coefficient may be applied to the filter layer 60. For example, an upper limit of the wavelength range specifying the cutoff region of the long pass filter may be a wavelength longer than the absorption edge wavelength λg of the single-crystal semiconductor layer 20. FIG. 4A depicts such a transmittance characteristic of the long pass filter. A lower limit of the wavelength range specifying the transmission region of the band pass filter may be a wavelength longer than the absorption edge wavelength λg of the single-crystal semiconductor layer 20. FIG. 4B depicts such a transmittance characteristic of the band pass filter.

In the example illustrated in FIG. 4A or 4B, it is assumed that the wavelength intended to be used in the imaging is 1400 nm and the single-crystal semiconductor layer 20 is made of single-crystal silicon. Because the absorption edge wavelength λg of the single-crystal silicon is 1100 nm, a wavelength range where the single-crystal silicon has a high absorption coefficient falls entirely within the cutoff region of the filter. In the case of the long pass filter, for example, the transmission region may be set to a wavelength range from 1200 nm to 1600 nm, and the cutoff region may be set to a wavelength range from 350 nm to 1100 nm. In the case of the band pass filter, for example, the transmission region may be set to a wavelength range from 1350 nm to 1450 nm, and the cutoff region may be set to a wavelength range obtained by excluding the above-mentioned transmission region from an entire wavelength range of 350 nm to 1600 nm.

If the single-crystal semiconductor layer 20 absorbs light, there is a possibility that charges are generated attributable to absorption of the light. Those charges are not intended in the operation of the imaging device and hence may cause noise and a malfunction. Accordingly, by setting the filter characteristic of the filter layer 60 such that the entirety or large part of the wavelength range where the single-crystal semiconductor layer 20 has the high absorption coefficient falls within the cutoff region, the absorption of the light in the single-crystal semiconductor layer 20 can be suppressed, and a larger amount of the light can be introduced to reach the photoelectric conversion layer 30. As a result, the noise and the malfunction can be reduced without deteriorating the sensitivity of the imaging device. However, the filter layer 60 is not essential.

The protective layer 70 may be a transparent film, such as a silicon oxide film or a silicon nitride film, which has low permeability for moisture, oxygen, and so on. The protective layer 70 provides an effect of suppressing change over time of device characteristics.

According to this embodiment, it is possible to suppress a reduction in sensitivity of imaging in a wavelength range on a longer wavelength side than the visible range, particularly in a near-infrared range. Hence the noise and the malfunction can be reduced without deteriorating the sensitivity of the imaging device.

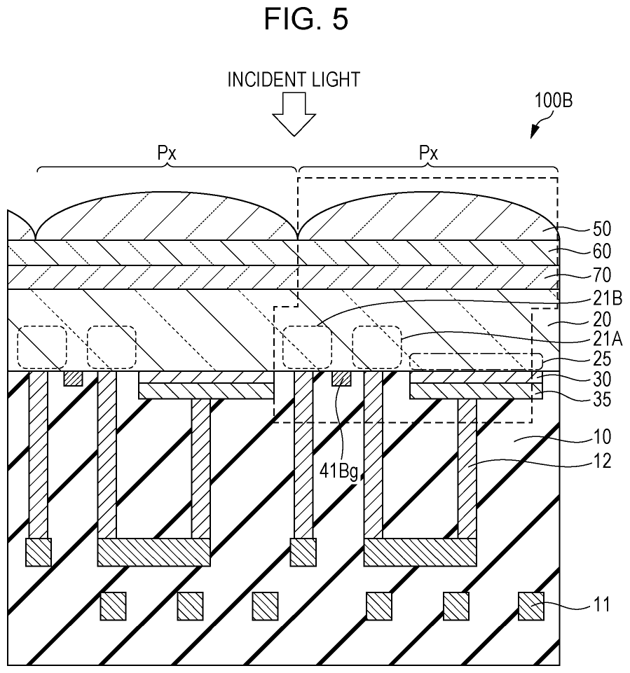

FIG. 5 is a schematic view illustrating, by way of example, a device structure of a pixel Px in an imaging device 100B according to a modification of the first embodiment. In FIG. 5, an area constituting the pixel Px is denoted by a dashed line. The pixel Px in the imaging device 100B is different in structure from the pixel Px in the above-described imaging device 100A in that the counter electrode 35 and the charge accumulation region 21A formed inside the single-crystal semiconductor layer 20 are electrically connected via a wiring layer. The following description is made mainly about different points from the imaging device 100A, and description of common points is omitted.

Of the charge pairs generated in the photoelectric conversion layer 30, an amount of the charges collected into the counter electrode 35 is measured. In this modification, the counter electrode 35 and the charge accumulation region 21A, the latter being formed inside the single-crystal semiconductor layer 20, are electrically connected via the wirings 11 and 12. For example, the positive charges collected into the counter electrode 35 are moved to the charge accumulation region 21A through the wirings 11 and 12 and are accumulated therein. Finally, the charge amount is measured by the column signal processing circuit 44.

A region 25 defined by a portion of the single-crystal semiconductor layer 20 to be in contact with the photoelectric conversion layer 30 and to serve as the charge collection region is a region different from the charge accumulation region 21A. The region 25 is electrically connected to, for example, an external power supply or an external constant potential line, and the charges collected into the region 25 is purged out to the outside of the single-crystal semiconductor layer 20. The photoelectric conversion layer 30 is sandwiched between the region 25 in the single-crystal semiconductor layer 20 and the counter electrode 35. The region 25 and the charge accumulation region 21A may be electrically separated from each other. For example, the polarity of an impurity doped into the region 25 may be different from that of an impurity doped into the charge accumulation region 21A. Alternatively, an insulating region may be disposed between those two regions. With such electrical separation, the charges collected into the region 25 can be prevented or suppressed from moving to the charge accumulation region 21A. This modification can also provide the same effect as that described in the above embodiment.

### Second Embodiment

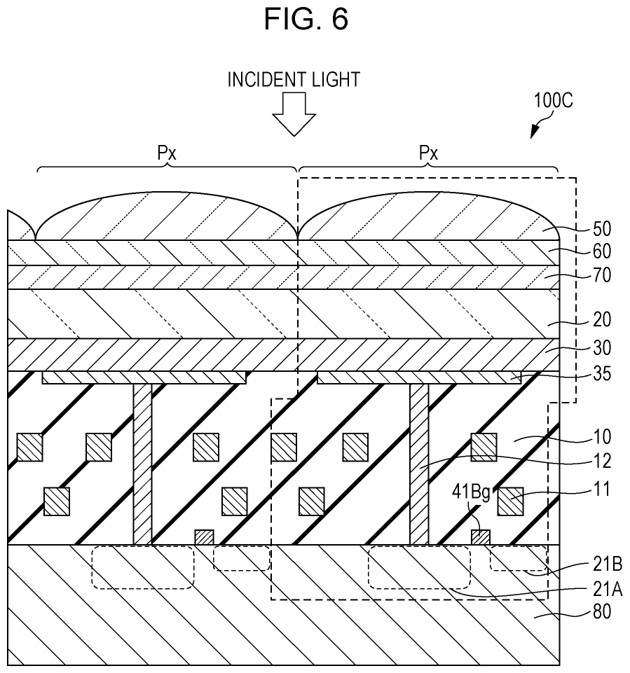

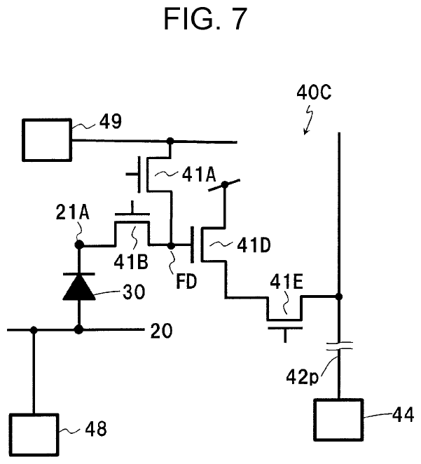

FIG. 6 is a schematic view illustrating, by way of example, a device structure of a pixel Px in an imaging device 100C according to a second embodiment. In FIG. 6, an area constituting the pixel Px is denoted by a dashed line. FIG. 7 is a circuit diagram illustrating a configuration example of a read circuit 40C in the second embodiment. The pixel Px in the imaging device 100C is different in structure from the pixel Px in the imaging device 100A according to the first embodiment in that the former pixel Px includes another single-crystal semiconductor layer 80, namely a second single-crystal semiconductor layer, different from the single-crystal semiconductor layer 20 and further includes a charge accumulation region 21A formed inside the single-crystal semiconductor layer 80. The following description is made mainly about different points from the imaging device 100A, and description of common points is omitted.

Of the charge pairs generated in the photoelectric conversion layer 30, the charges collected into the counter electrode 35 are accumulated into the charge accumulation region 21A, which is formed at a position outside the single-crystal semiconductor layer 20, and are then measured. The charge accumulation region 21A is formed, for example, inside the other single-crystal semiconductor layer 80 different from the single-crystal semiconductor layer 20. In this embodiment, the pixel Px includes the single-crystal semiconductor layer 80 positioned on an opposite side to the single-crystal semiconductor layer 20 with respect to the insulating layer 10. The single-crystal semiconductor layer 80, the insulating layer 10, the photoelectric conversion layer 30, and the single-crystal semiconductor layer 20 are laminated in order mentioned. The insulating layer 10 and the photoelectric conversion layer 30 are sandwiched between the two single-crystal semiconductor layers 20 and 80.

As illustrated in FIG. 7, the single-crystal semiconductor layer 20 is electrically connected to a bias voltage control circuit 48 for controlling a voltage of the single-crystal semiconductor layer 20. The bias voltage control circuit 48 is, for example, a constant voltage source, a variable voltage source, or a ground line. The electrical connection of the single-crystal semiconductor layer 20 may be realized by providing a contact portion on any one of an upper surface, a lateral surface, or a lower surface of the single-crystal semiconductor layer 20. For example, wire bonding can be used as a method of providing the contact portion on the upper surface. A method of providing the contact portion on the lower surface may be carried out by forming, inside the insulating layer 10, a wiring for connection to the bias voltage control circuit 48, and by connecting the wiring to the single-crystal semiconductor layer 20 in a region where the photoelectric conversion layer 30 is not present.

The counter electrode 35 is connected to the charge accumulation region 21A formed inside the single-crystal semiconductor layer 80 via the wiring 12. The counter electrode 35 collects, for example, the positive charges generated in the photoelectric conversion layer 30. The positive charges collected into the counter electrode 35 are moved to the charge accumulation region 21A through the wiring 12 and are accumulated therein. As in the first embodiment, another charge accumulation region 21B may be formed inside the single-crystal semiconductor layer 80 in addition to the charge accumulation region 21A, but the charge accumulation region 21B is not essential.

The read circuit 40C may be formed inside the single-crystal semiconductor layer 80. A channel region, a source region, and a drain region of each transistor can be integrated in the single-crystal semiconductor layer 80. The read circuit 40C includes a reset transistor 41A, a transfer transistor 41B, an amplifier transistor 41D, and a selection transistor 41E. However, the transfer transistor 41B is not essential. As in the read circuit 40 in the first embodiment, the read circuit 40C may further include a read transistor for transferring the charges accumulated in the charge accumulation region 21B to a floating diffusion node FD.

The floating diffusion node FD is connected, via the reset transistor 41A, to a bias voltage control circuit 49 for controlling a voltage. When the bias voltage control circuit 49 is electrically connected to the floating diffusion node FD, it controls a voltage at the floating diffusion node FD to a specified value. In practice, the bias voltage control circuit 49 may be constituted by, for example, a constant voltage line or a constant voltage power supply. The reset transistor 41A can cut off electrical connection between the floating diffusion node FD and the bias voltage control circuit 49, thereby enabling the charges to be accumulated at the floating diffusion node FD. On the other hand, when the floating diffusion node FD is to be reset, the reset transistor 41A electrically connects the bias voltage control circuit 49 to the floating diffusion node FD and sets the voltage at the floating diffusion node FD to the specified value. The voltage of the counter electrode 35 can be set to the specified value with the bias voltage control circuit 49 by bringing both the reset transistor 41A and the transfer transistor 41B to a conduction state.

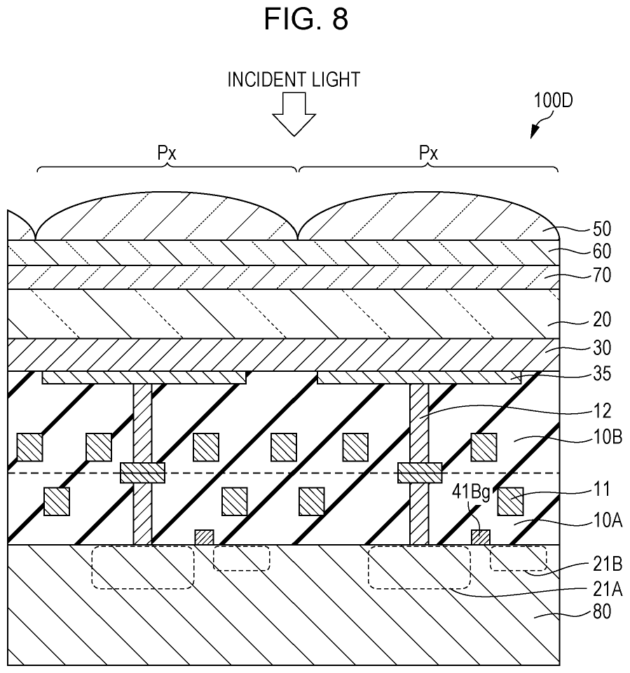

FIG. 8 is a schematic view illustrating, by way of example, a device structure of a pixel Px in an imaging device 100D according to a modification of the second embodiment. The insulating layer 10 includes a first portion 10A and a second portion 10B. The imaging device 100D can be obtained by separately fabricating a multilayer structure of the first portion 10A of the insulating layer 10 and the single-crystal semiconductor layer 80 and a multilayer structure of the second portion 10B of the insulating layer 10, the photoelectric conversion layer 30, and the single-crystal semiconductor layer 20, and by bonding those two separately fabricated multilayer structures to each other. With this modification, a manufacturing process of the imaging device can be simplified.

### Third Embodiment

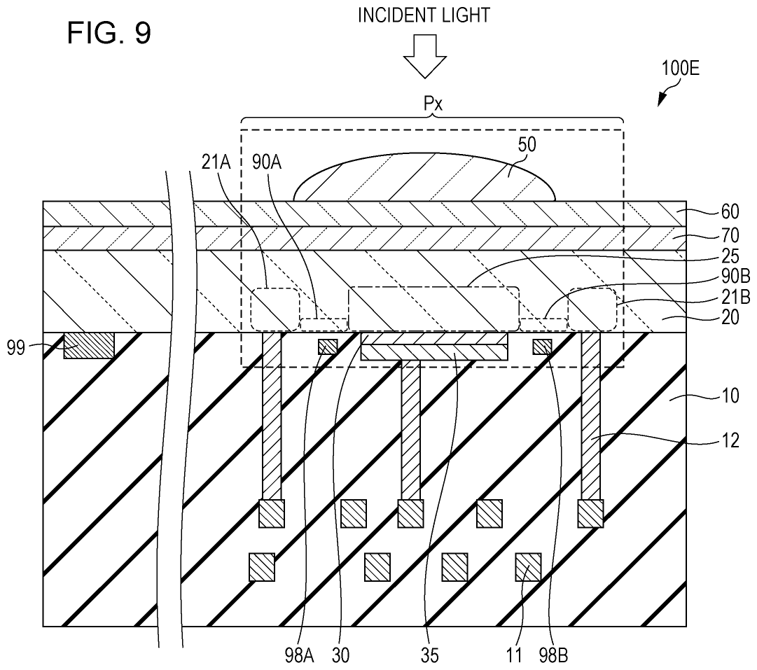

FIG. 9 is a schematic view illustrating, by way of example, a device structure of a pixel Px in an imaging device 100E according to a third embodiment. In FIG. 9, an area constituting the pixel Px is denoted by a dashed line. The imaging device 100E according to the third embodiment may be designed so as to mainly obtain a distance image.

The photoelectric conversion layer 30 is in direct contact with a region 25 inside the single-crystal semiconductor layer 20 or is electrically connected to the region 25 through a layer in which the charges are movable. The positive charges or the negative charges generated with the photoelectric conversion in the photoelectric conversion layer 30 can be moved to the region 25 from the photoelectric conversion layer 30. For example, in the case of enabling the positive charges to be moved from the photoelectric conversion layer 30 to the region 25, the doping just needs to be performed such the region 25 becomes the p-type. On the other hand, in the case of enabling the negative charges to be moved from the photoelectric conversion layer 30 to the region 25, the doping just needs to be performed such that the region 25 becomes the n-type.

In the illustrated example, an electrode 99 is disposed inside the insulating layer 10 at a position except for the area of the pixel Px and is in contact with the single-crystal semiconductor layer 20. The electrode 99 is an electrode for controlling a potential of the single-crystal semiconductor layer 20. An internal electric field depending on a voltage determined according to a potential of the electrode 99 and a potential of the electrode 35 is generated inside the photoelectric conversion layer 30. The hole-electron pairs including the positive charges and the negative charges are generated upon the photoelectric conversion layer 30 absorbing light. Under the internal electric field, either the positive charges or the negative charges are moved to the region 25 inside the single-crystal semiconductor layer 20, and the other charges are moved to the electrode 35. Thus, of the positive charges and the negative charges generated in the photoelectric conversion layer 30. the charges not moved to the region 25 are collected by the electrode 35.

In this embodiment, for the photoelectric conversion layer 30 belonging to each pixel Px, at least two or more charge accumulation regions 21 are formed inside the single-crystal semiconductor layer 20. In the illustrated example, two charge accumulation regions 21A and 21B are formed. Electrodes 98A and 98B are disposed inside the insulating layer 10 at positions near the charge accumulation regions 21A and 21B, respectively. The charge accumulation region 21A and the electrode 98A are electrically insulated from each other, and the charge accumulation region 21B and the electrode 98B are electrically insulated from each other. As a result, a direct current does not flow between the charge accumulation region 21A and the electrode 98A and between the charge accumulation region 21B and the electrode 98B. In addition to the charge accumulation regions 21A and 21B, one or more charge accumulation regions may be further formed inside the single-crystal semiconductor layer 20. Thus, the number of charge accumulation regions that may be formed inside the single-crystal semiconductor layer 20 is not limited to two and may be three or four or more.

A channel region 90A is formed between the region 25 and the charge accumulation region 21A, and a channel region 90B is formed between the region 25 and the charge accumulation region 21B. Electrical conductivity of the channel region 90A can be controlled by a voltage applied to the electrode 98A. Similarly, electrical conductivity of the channel region 90B can be controlled by a voltage applied to the electrode 98B.

To explain in more detail, the channel region 90A can be brought into a conduction state by applying a voltage within a first voltage range to the electrode 98A. As a result, the charges become movable between the region 25 and the charge accumulation region 21A. Furthermore, the channel region 90A can be brought into a cutoff state by applying a voltage within a second voltage range different from the first voltage range to the electrode 98A. As a result, the movement of the charges between the region 25 and the charge accumulation region 21A can be inhibited.

As in the channel region 90A, the channel region 90B can be brought into a conduction state by applying a voltage within a third voltage range to the electrode 98B. As a result, the charges become movable between the region 25 and the charge accumulation region 21B. Furthermore, the channel region 90B can be brought into a cutoff state by applying a voltage within a fourth voltage range different from the third voltage range to the electrode 98B. As a result, the movement of the charges between the region 25 and the charge accumulation region 21B can be inhibited. The first voltage range may be the same as or different from the third voltage range. Similarly, the second voltage range may be the same as or different from the fourth voltage range.

The voltage applied to the electrode 98A and the voltage applied to the electrode 98B may be controlled independently or in synchronism. For example, when the voltage within the first voltage range is applied to the electrode 98A and the voltage within the fourth voltage range is applied to the electrode 98B, the charges in the region 25 can be moved to the charge accumulation region 21A, but cannot be moved to the charge accumulation region 21B. Similarly, when the voltage within the second voltage range is applied to the electrode 98A and the voltage within the third voltage range is applied to the electrode 98B, the charges in the region 25 can be moved to the charge accumulation region 21B, but cannot be moved to the charge accumulation region 21A. Thus, by appropriately changing the voltage applied to the electrode 98A and the voltage applied to the electrode 98B over time, the charges generated in the photoelectric conversion layer 30 can be distributed to the charge accumulation region 21A and the charge accumulation region 21B in accordance with the time of generation of the charges in the photoelectric conversion layer 30. As another example, when a further charge accumulation region is formed inside the single-crystal semiconductor layer 20, the charges generated in the photoelectric conversion layer 30 can be distributed to the three charge accumulation regions in accordance with the time of generation of the charges in the photoelectric conversion layer 30.

As described above, the electrical conductivity of the channel region 90A can be controlled by the voltage applied to the electrode 98A. This implies that the region 25, the charge accumulation region 21A, the channel region 90A, and the electrode 98A function respectively as a source region, a drain region, a channel, and a gate electrode of a field effect transistor. Similarly, the electrical conductivity of the channel region 90B can be controlled by the voltage applied to the electrode 98B. This implies that the region 25, the charge accumulation region 21B, the channel region 90B, and the electrode 98B function respectively as a source region, a drain region, a channel, and a gate electrode of a field effect transistor.

The functions of those field effect transistors can be realized, for example, by performing the doping on the region 25, the charge accumulation region 21A, and the charge accumulation region 21B to have the same polarity, performing the doping on the channel region 90A and the channel region 90B to have a polarity different from that of the region 25, and by forming a thin insulating layer in each of zones between the electrode 98A and the channel region 90A and between the electrode 98B and the channel region 90B.

The charge accumulation region 21A and/or the charge accumulation region 21B may be electrically connected the constant potential line or the ground line via the wirings 11 and 12. This electrical connection enables the charges accumulated in the charge accumulation region to be released for resetting.

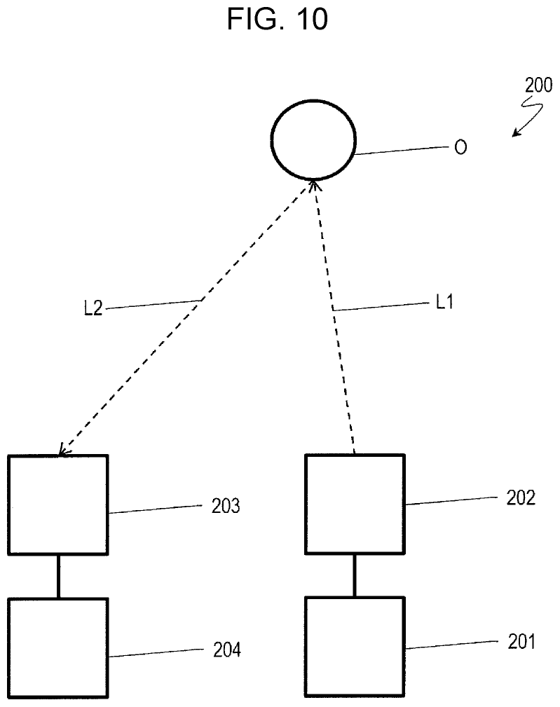

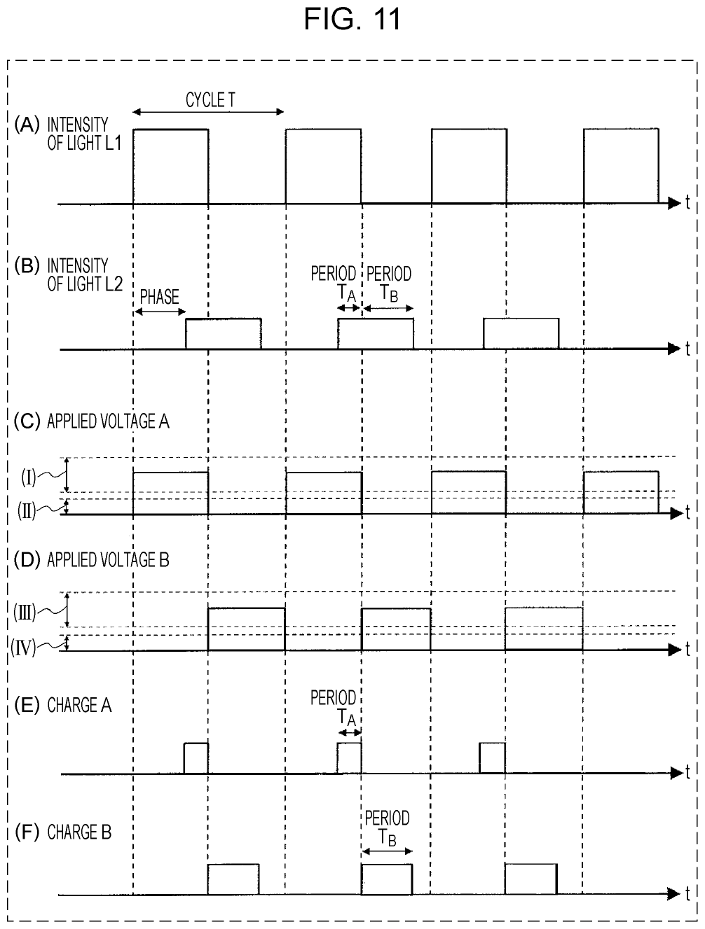

FIG. 10 is a block diagram illustrating a configuration example of a distance image acquisition system 200 according to this embodiment. FIG. 11 is an explanatory view illustrating the principle of operation of the distance image acquisition system 200 according to this embodiment. In FIG. 11, the above-described first voltage range, second voltage range, third voltage range, and fourth voltage range are denoted by arrows (I), (II), (III), and (IV), respectively.

The distance image acquisition system 200 includes a light source 201, optical systems 202 and 203, and an imaging device 204. For example, the above-described imaging device 100E can be used as the imaging device 204.

The light source 201 may include, for example, a laser diode and/or a light emitting diode that is controlled by a drive current. The light source 201 generates and emits, for example, light L1 with intensity changing over time, namely AM-modulated light.

The optical system 202 has a function of shaping the light L1 with the intensity changing over time, emitted from the light source 201, and applying the light L1 to an object 0. Such a function is basically equivalent to that of a general illumination optical system, and hence detailed description of the function is omitted.

The optical system 203 has a function of focusing, on the imaging device 204, reflected light L2 from the object O having been illuminated with the light L1. Such a function is also basically equivalent to that of a general imaging optical system, and hence detailed description of the function is omitted.

The principle of operation of the distance image acquisition system 200 will be described below with reference to FIG. 11.

The principle of acquiring an image by the distance image acquisition system 200 is the same as that used in a general TOF (Time Of Flight) image sensor. The light source 201 generates and emits the light L1 with the intensity changing over time at a cycle T. In the illustrated example, the light L1 with the intensity being 0 for a period of T/2 and being constant for the remaining period of T/2 is emitted from the light source 201.

The object O is illuminated with the light L1 after being shaped through the optical system 202, and the light L2, namely the reflected light from the object O, is focused on the imaging device 204 through the optical system 203. As a result, an image of the object O is formed on a pixel array of the imaging device 204. The light L2 reflected from parts of the object O corresponding to parts in the formed image is incident on the pixels Px of the imaging device 204 in a one-to-one relation.

Intensity of the light L2 incident on each pixel Px changes at the same cycle T as the light L1. Phase of the light L2 changes depending on the sum of a distance from the optical system 202 to the object O and a distance from the object O to the optical system 203. Thus, the phase contains information about a distance up to the object O. It is here assumed that a voltage A applied to the electrode 98A and a voltage B applied to the electrode 98B, both the electrodes being included in each pixel Px of the imaging device 204, are changed as illustrated, by way of example, in FIG. 11. More specifically, during the period of T/2, the applied voltage A within the first voltage range (I) is applied to the electrode 98A, and the applied voltage B within the fourth voltage range (IV) is applied to the electrode 98B. During the next period of T/2, the applied voltage A within the second voltage range (II) is applied to the electrode 98A, and the applied voltage B within the third voltage range (III) is applied to the electrode 98B. In this case, the charges generated in the photoelectric conversion layer 30 during a period TA are collected as charges A into the charge accumulation region 21A, and the charges generated in the photoelectric conversion layer 30 during a period TB are collected as charges B into the charge accumulation region 21B.

A ratio between the charges A generated during the period TA to the charges B generated during the period TB is determined depending on the phase of the light L2 incident on each pixel Px. Therefore, the phase of the light L2 incident on each pixel Px can be determined by measuring an amount of the charges A collected into the charge accumulation region 21A and an amount of the charges B collected into the charge accumulation region 21B. The sum of the distance from the optical system 202 to the object O and the distance from the object O to the optical system 203 can be calculated on the basis of the determined phase of the light L2.

The imaging device 100E according to this embodiment can be utilized as a device acquiring a distance image, particularly as an imaging device mounted on an autonomous vehicle. Furthermore, according to the imaging device 100E, as with the other embodiments, higher sensitivity can be realized for light at a long wavelength, for example, 1400 nm, in comparison with the related-art multilayer image sensor utilizing the ITO film as the transparent electrode. As a result, high sensitivity can be obtained even in the near-infrared range.

### Fourth Embodiment

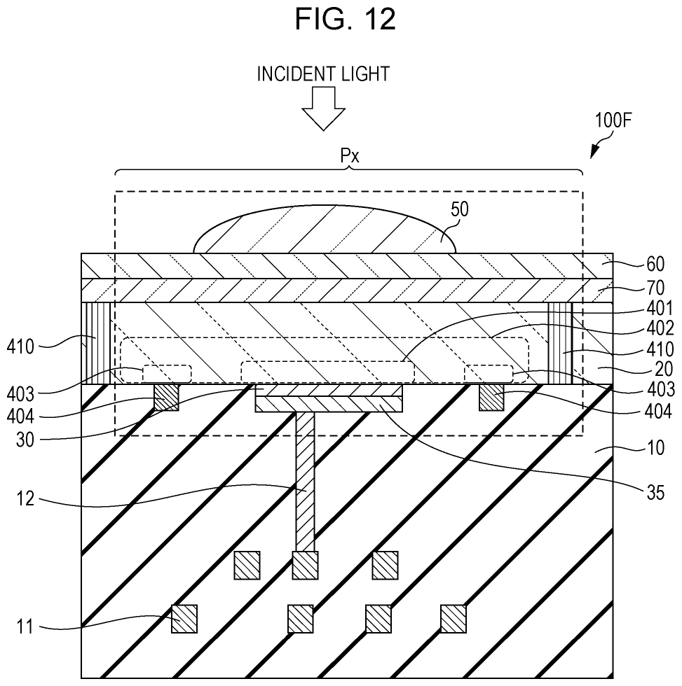

FIG. 12 is a schematic view illustrating, by way of example, a device structure of a pixel Px in an imaging device 100F according to a fourth embodiment. In FIG. 12, an area constituting the pixel Px is denoted by a dashed line.

The imaging device 100F according to the fourth embodiment includes an avalanche amplification mechanism. The avalanche amplification mechanism may be constituted by, for example, two regions 401 and 402 inside the single-crystal semiconductor layer 20 as described later.

The photoelectric conversion layer 30 is in direct contact with the region 401 inside the single-crystal semiconductor layer 20 or is electrically connected to the region 401 through a layer in which the charges are movable. The positive charges or the negative charges generated with the photoelectric conversion in the photoelectric conversion layer 30 can be moved to the region 401 from the photoelectric conversion layer 30. The region 401 is made of a single-crystal semiconductor and has a p-type or n-type polarity. The region 401 is in contact with the region 402 inside the single-crystal semiconductor layer 20. Like the region 401, the region 402 is made of a single-crystal semiconductor and has a p-type or n-type polarity. The polarity of the region 402 is different from that of the region 401.

In this embodiment, a region 403 may be further formed inside the single-crystal semiconductor layer 20. The region 403 is in contact with the region 402 but is not in contact with the region 401. Like the regions 401 and 402, the region 403 is made of a single-crystal semiconductor and has a p-type or n-type polarity. The polarity of the region 403 is the same as that of the region 402. However, a dopant concentration in the region 403 is higher than in the region 402.

The region 403 is electrically connected to an electrode 404 formed inside the insulating layer 10. At least one of the electrode 35 or the electrode 404 may be electrically connected to, for example, the column signal processing circuit 44, a current amount measurement circuit (not illustrated), or a current generation detection circuit (not illustrated). As illustrated in the drawing, an isolation region or a trench 410 for providing electrical insulation between adjacent two of the pixels Px may be disposed as required.

A potential difference is applied to between the regions 401 and 402 by a voltage control circuit (not illustrated). The charges passing near a boundary between the regions 401 and 402 are accelerated by an internal electric field generated due to the above-mentioned potential, whereby avalanche amplification can be developed. Thus, the regions 401 and 402 are able to function as the avalanche amplification mechanism.

The above-described avalanche amplification can be generated attributable to the charges generated in the photoelectric conversion layer 30. Therefore, the charges generated in the photoelectric conversion layer 30 can be amplified. As a result, it becomes possible to realize imaging of, for example, weak light in a dark place such as at night. Furthermore, the avalanche amplification mechanism may be operated in the so-called Geiger mode. In other words, a current state can be usually held in an off-state in which no current flows. When the charges generated in the photoelectric conversion layer 30 reach the avalanche amplification mechanism, the current state can be transited from the off-state to an on-state in which a current flows. By detecting the time of generation of the current with the current generation detection circuit, the imaging device 100F can be operated as the so-called direct TOF sensor.

Since the imaging device according to the present disclosure can ensure high sensitivity even in the near-infrared range, the imaging device can be utilized in various applications, for example, Machine Vision, outdoor monitoring in self-driving or the like, and medical care, in which imaging in the near-infrared range is required.

What is claimed is:

1. An imaging device comprising:
pixels, each of the pixels including:
a first single-crystal semiconductor layer transmitting light;
a first electrode; and
a photoelectric conversion layer in contact with the first single-crystal semiconductor layer, the photoelectric conversion layer being positioned between the first single-crystal semiconductor layer and the first electrode and absorbing the light,
wherein the first single-crystal semiconductor layer, the photoelectric conversion layer, and the first electrode are arranged in order mentioned such that the light after passing through the first single-crystal semiconductor layer is incident on the photoelectric conversion layer.

2. The imaging device according to claim 1, further comprising a bias voltage control circuit electrically connected to at least one selected from the group consisting of the first single-crystal semiconductor layer and the first electrode, the bias voltage control circuit applying a bias voltage to the photoelectric conversion layer.

3. The imaging device according to claim 1, wherein each of the pixels further includes a charge accumulation region positioned in the first single-crystal semiconductor layer and accumulating charges generated in the photoelectric conversion layer.

4. The imaging device according to claim 3, wherein each of the pixels further includes a read circuit positioned in the first single-crystal semiconductor layer and reading out the charges accumulated in the charge accumulation region.

5. The imaging device according to claim 1, wherein
each of the pixels further includes:
a second single-crystal semiconductor layer; and
a charge accumulation region positioned in the second single-crystal semiconductor layer and accumulating charges generated in the photoelectric conversion layer, and
the first electrode is positioned between the first single-crystal semiconductor layer and the second single-crystal semiconductor layer.

6. The imaging device according to claim 5, wherein each of the pixels further includes a read circuit positioned in the second single-crystal semiconductor layer and reading out the charges accumulated in the charge accumulation region.

7. The imaging device according to claim 1, wherein each of the pixels further includes:
an on-chip lens; and
a filter layer positioned between the on-chip lens and the first single-crystal semiconductor layer, the filter layer selectively transmitting light in a first wavelength range.

8. The imaging device according to claim 7, wherein the filter layer has a filter characteristic having a transmission region in the first wavelength range and a cutoff region in a second wavelength range shorter than the first wavelength range.

9. The imaging device according to claim 7, wherein the filter layer has a filter characteristic having a transmission region in the first wavelength range, a first cutoff region in a second wavelength range shorter than the first wavelength range, and a second cutoff region in a third wavelength range longer than the first wavelength range.

10. The imaging device according to claim 7, wherein the filter layer has a filter characteristic having a cutoff region in a wavelength range in which the first single-crystal semiconductor layer absorbs light.

11. The imaging device according to claim 1, wherein
the first single-crystal semiconductor layer is made of silicon, and
the photoelectric conversion layer absorbs light having a wavelength of 1100 nm or longer.

12. The imaging device according to claim 1, wherein the photoelectric conversion layer is made of a material selected from the group consisting of an organic semiconductor, a semiconductor carbon nanotube, and a semiconductor quantum dot.

13. The imaging device according to claim 1, wherein each of the pixels further includes:
a charge collection region positioned in the first single-crystal semiconductor layer and collecting charges generated in the photoelectric conversion layer;
a first charge accumulation region positioned in the first single-crystal semiconductor layer, the first charge accumulation region being different from the charge collection region and accumulating the charges;
a second charge accumulation region positioned in the first single-crystal semiconductor layer, the second charge accumulation region being different from the charge collection region and accumulating the charges;
a second electrode electrically insulated from the first charge accumulation region;
a third electrode electrically insulated from the second charge accumulation region;
a first channel region positioned between the charge collection region and the first charge accumulation region; and
a second channel region positioned between the charge collection region and the second charge accumulation region.

14. The imaging device according to claim 13, wherein
movement of the charges in the first channel region from the charge collection region to the first charge accumulation region is controlled by controlling a voltage applied to the second electrode, and
movement of the charges in the second channel region from the charge collection region to the second charge accumulation region is controlled by controlling a voltage applied to the third electrode.

15. The imaging device according to claim 1, further comprising an avalanche amplification mechanism capable of generating avalanche amplification.

16. The imaging device according to claim 15, wherein
the avalanche amplification mechanism includes;
a first region positioned in the first single-crystal semiconductor layer and collecting charges generated in the photoelectric conversion layer; and
a second region positioned in the first single-crystal semiconductor layer and being in contact with the first region, and
a polarity of the first region is different from a polarity of the second region.

17. The imaging device according to claim 16, wherein
the avalanche amplification mechanism further includes a third region positioned in the first single-crystal semiconductor layer and being in contact with the second region,
the third region has the same polarity as the second region, and
a dopant concentration of the third region is higher than a dopant concentration of the second region.
